(19) United States
(12) Patent Application Publication
(10) Pub. No.: US 2008/0237844 A1
(43) Pub. Date: Oct. 2, 2008

(54) Microelectronic package and method of manufacturing same

(76) Inventors: Aleksandar Aleksov, Chandler, AZ (US); Vladimir Noveski, Chandler, AZ (US); Sujit Sharan, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/729,200

(22) Filed: Mar. 28, 2007

(51) Int. Cl. H01L 23/36

(52) U.S. Cl. 257/713

(57) ABSTRACT

A microelectronic package includes a package substrate (110, 310, 410), a plurality of dies (120, 610, 630) arranged in a stack (150, 350, 450) above the package substrate, with a first die (121) located above the package substrate at a bottom (151) of the stack and an uppermost die (122) located at a top (152) of the stack, and a plurality of heat spreaders (130, 330, 430, 620) stacked above the first die, with a first heat spreader (131) located above the uppermost die. One of the plurality of heat spreaders is located between each pair of adjacent dies. Each one of the plurality of heat spreaders has an extending portion (132) that extends laterally beyond an edge (123) of an adjacent die, and at least one of the plurality of heat spreaders both provides electrical interconnectivity and thermal conductivity.

### FIELD OF THE INVENTION

The disclosed embodiments of the invention relate generally to thermal management and mechanical integrity of microelectronic packaging, and relate more particularly to package-level thermo-mechanical management solutions for stacked die packages.

### BACKGROUND OF THE INVENTION

Until recently, thermal management in microelectronic packages was focused on the task of removing heat from single-die packages or from packages having a small number of dies side-by-side. Typically in such environments a thermally-conducting integrated heat spreader has been placed over the die or dies for the purpose of heat removal. The overlying integrated heat spreader approach has worked well for single-die packages and for packages having dies stacked side-by-side, but the movement toward stacked die packages calls for a new approach to thermal management and mechanical integrity of the products. A heat spreader placed at the top of a stack of dies is unable to adequately remove heat from dies below the top of the stack, and those dies, being surrounded or partially surrounded by other heat-producing dies, will quickly overheat and sustain damage if not properly dealt with thermally. Accordingly, there exists a need for a thermal management solution capable of addressing the thermal management needs of stacked die packages.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a portion of a microelectronic package according to an embodiment of the invention;

FIG. 2 is a perspective view of the microelectronic package of FIG. 1 according to an embodiment of the invention;

FIG. 3 is a perspective view of a different microelectronic package according to an embodiment of the invention;

FIG. 4 is a perspective view of a different microelectronic package according to an embodiment of the invention;

FIG. 5 is a flowchart illustrating a method of manufacturing a microelectronic package according to an embodiment of the invention; and

FIG. 6 is a cross-sectional view of a portion of a microelectronic package according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic package comprises a package substrate, a plurality of dies arranged in a stack above the package substrate, with a first die located above the package substrate at a bottom of the stack and an uppermost die located at a top of the stack, and a plurality of heat spreaders stacked above the first die, with a first heat spreader located above the uppermost die. One of the plurality of heat spreaders is located between each pair of adjacent dies. At least one of the plurality of heat spreaders provides both electrical interconnectivity and thermal conductivity.

In one embodiment, each one of the plurality of heat spreaders has an extending portion that extends laterally beyond an edge of an adjacent die. In a different embodiment, each one of the plurality of heat spreaders is approximately the same size as an adjacent die such that no part of each heat spreader extends beyond a perimeter of the adjacent die. As an example, this embodiment may offer enhanced mechanical benefits for low-power products. In another embodiment, each one of the plurality of heat spreaders is smaller than an adjacent die such that a portion of the dies extend beyond an edge of an adjacent heat spreader. As an example, each side of the heat spreaders can be approximately 10% smaller than a corresponding side of an adjacent die. As another example, this embodiment could employ heat spreaders having a thickness of several millimeters.

Embodiments of the invention address thermal management at the package level and allow for increased design flexibility, possibly at reduced cost. The heat extraction solutions presented herein are part of the assembly process rather than relying on materials integrated as part of the semiconductor substrate, thus allowing for the integration of multiple heterogeneous components. The assembly oriented design allows for separate development, production, and test of every element required and thus allows a far more independent optimization of circuitry design and heat extraction solutions than does a solution integrated into the semiconductor manufacturing process. As a result, embodiments of the invention provide high potential for cost reduction and yield improvement. Embodiments of the invention incorporate through silicon vias and through heat spreader vias and thus provide for a minimum z-dimension (height) of the package that maximizes the density and computational performance of the package components per unit area.

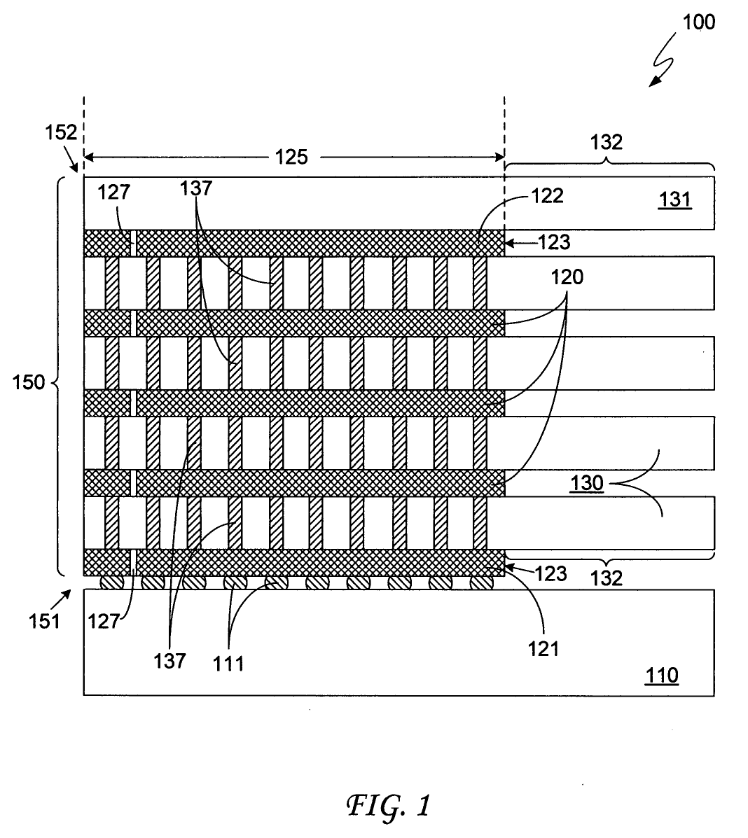

Referring now to the figures, FIG. 1 is a cross-sectional view of a portion of a microelectronic package 100 according to an embodiment of the invention. The portion shown represents approximately the right half of microelectronic package 100, with the non-illustrated left half being a mirror image of the illustrated right half. As illustrated in FIG. 1, microelectronic package 100 comprises a package substrate 110 and a plurality of dies 120 arranged in a stack 150 above package substrate 110, with a die 121 located above package substrate 110 at a bottom 151 of stack 150 and a die 122 located at a top 152 of stack 150. Microelectronic package 100 further comprises a plurality of heat spreaders 130 stacked above die 121, with a heat spreader 131 located above die 122. In the illustrated embodiment, die 121 is electrically and physically connected to package substrate 110 via flip chip interconnects 111.

Each occurrence of two dies next to each other without any other dies in between constitutes what is referred to herein as a pair of adjacent dies. In the illustrated embodiment, a heat spreader from plurality of heat spreaders 130 is located between each pair of adjacent dies in stack 150. Each one of plurality of heat spreaders 130 has an extending portion 132 that extends laterally beyond an edge 123 of an adjacent one of plurality of dies 120. In the illustrated embodiment, extending portions 132 extend laterally beyond edges 123 of all of plurality of dies 120. In the same or another embodiment, if dies 120 have a width 125, a length of extending portions 132 is at least approximately 25 percent larger than width 125. More generally, in one embodiment a length of an extending portion 132 is at least approximately 25 larger than a length of an adjacent one of plurality of dies 120. In at least one embodiment, extending portions 132 also extend laterally beyond a non-illustrated left edge of microelectronic package 100 in a manner that is the mirror image of what is shown in FIG. 1 at edges 123.

As an example, heat spreaders 130 may be made of a ceramic, a metal, a ceramic/metal composite, or the like. Examples of ceramic materials that could be used for heat spreaders 130 include aluminum nitride (AlN), silicon carbide (SiC), diamond, and diamond-like carbon. A decision regarding the use of diamond, diamond-like carbon, or another ceramic or non-ceramic material for heat spreader 130 may be made according to the requirements of the application for which heat spreader 130 is intended.

Of the ceramic materials mentioned above, diamond is likely to provide the highest thermal conductivity levels and thus the highest performance level for heat spreaders 130. At the same time, diamond-like carbon is likely to provide at least an adequate thermal conductivity level at a cost that is much less than that of actual diamond. Furthermore, diamond-like carbon may be grown at the relatively modest temperature of approximately 400-450 degrees Celsius—a number that may well decrease further as research in this field progresses. The ability to grow diamond-like carbon at these temperatures is a feature that may prove to be valuable in microelectronics manufacturing processes.

As known in the art, diamond-like carbon may be manufactured so as to fall somewhere along a spectrum of characteristics at one end of which the diamond-like carbon is rather like diamond and at the other end of which the diamond-like carbon is rather like graphite. In at least certain embodiments where heat spreaders 130 are made from diamond-like carbon, the diamond-like carbon is manufactured so as to be electrically insulating such that heat spreaders 130 do not create unwanted electrical shorts within microelectronic package 100. In other words, at least in terms of its electrical conductivity, such diamond-like carbon is manufactured to be more like the electrically insulating diamond than like the electrically conducting graphite.

At least one of plurality of heat spreaders 130 provides electrical interconnectivity while also providing thermal conductivity. Thermal conductivity, of course, is a characteristic exhibited by all useful heat spreaders as a requirement of performing their heat spreading function. Existing heat spreaders, however, have not necessarily needed to provide electrical interconnectivity, as further discussed below, microelectronic package 100 may benefit from the electrical interconnectivity provided by the at least one of heat spreaders 130. In the illustrated embodiment such electrical interconnectivity is provided by through heat spreader vias (THSV) 137 (hereinafter “vias 137”). Still referring to the illustrated embodiment, each one of plurality of heat spreaders 130, with the exception of heat spreader 131, contains vias 137. (It should be understood that apart from the electrical interconnectivity provided by vias 137, heat spreaders 130 are electrically insulating, as more fully discussed in the preceding paragraph.) In one embodiment, at least one of plurality of dies 120 contains a through silicon via (TSV) 127 (hereinafter “via 127”). In the illustrated embodiment, each one of dies 120 contains one via 127, but in other embodiments one or more of plurality of dies 120 may contain more than one via 127.

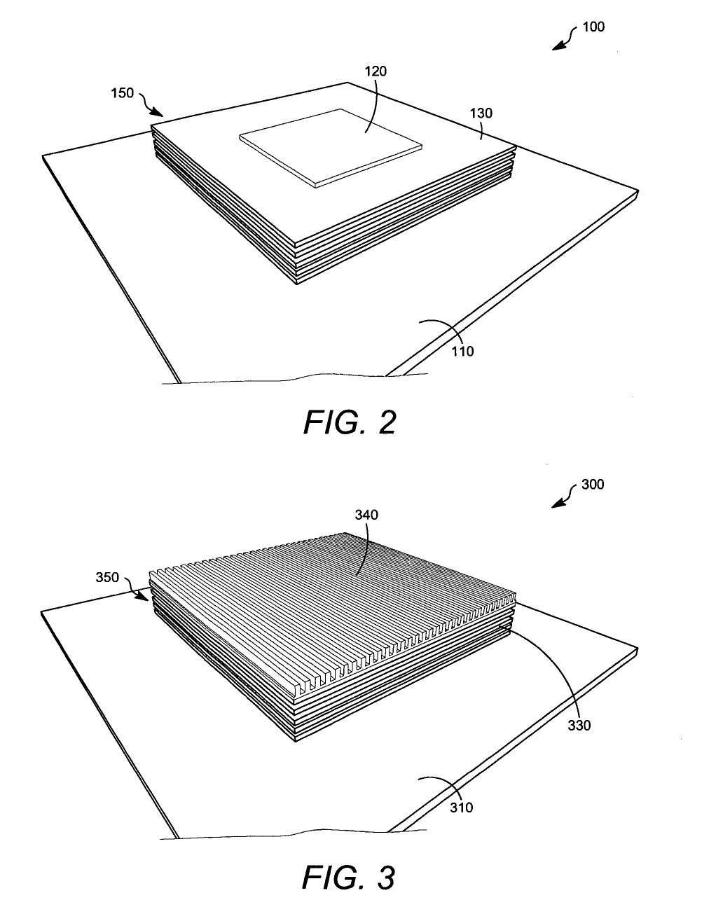

FIG. 2 is a perspective view of microelectronic package 100 according to an embodiment of the invention. FIG. 2 depicts stack 150 over package substrate 110. Visible in stack 150 are plurality of heat spreaders 130 (minus heat spreader 131) and an uppermost one of plurality of dies 120.

FIG. 3 is a perspective view of a microelectronic package 300 according to an embodiment of the invention. As illustrated in FIG. 3, microelectronic package 300 comprises a package substrate 310 and a stack 350 above package substrate 310 comprising a plurality of heat spreaders 330 and a plurality of dies (not visible) corresponding, for example, to plurality of dies 120 in FIG. 1. As another example, package substrate 310, stack 350, and plurality of heat spreaders 330 can be similar to, respectively, package substrate 110, stack 150, and plurality of heat spreaders 130, all of which are shown in FIG. 1. Microelectronic package 300 further comprises a microchannel or micro-machined heat sink 340 on top of stack 350. Heat sink 340 may be placed on top of an uppermost heat spreader of stack 350 or on top of an uppermost die of stack 350. If necessary, stack 350 and heat sink 340 may be surrounded by a lid (not shown) having openings for the circulation of a coolant. In various embodiments, air may be used as a coolant. In other embodiments, a liquid coolant may be used.

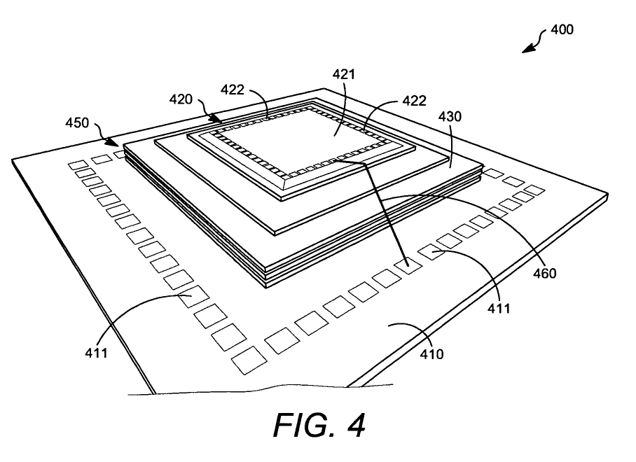

FIG. 4 is a perspective view of a microelectronic package 400 according to an embodiment of the invention. As illustrated in FIG. 4, microelectronic package 400 comprises a package substrate 410 and a stack 450 above package substrate 410 comprising a plurality of heat spreaders 430 and a plurality of dies 420 (of which only an uppermost one is visible). As an example, the plurality of dies can be similar to plurality of dies 120 that are shown in FIG. 1. As another example, package substrate 410, stack 450, plurality of dies 420, and plurality of heat spreaders 430 can be similar to, respectively, package substrate 110, stack 150, plurality of dies 120, and plurality of heat spreaders 130, all of which are shown in FIG. 1.

A die 421 is the aforementioned uppermost one of plurality of dies 420. Die 421 is physically and electrically connected to package substrate 410 using a wire bond 460 attached to bond pads 422 on die 421 and to bond pads 411 on package substrate 410. Flip chip interconnects (not shown in FIG. 4 but that may be similar to flip chip interconnects 111 shown in FIG. 1) may be used for at least one of the other dies in plurality of dies 420 such that microelectronic package 400 contains both wire bonds and flip chip interconnects. While such integration has already been demonstrated in assembly for low power products, it has not been demonstrated for high power products and for more than two dies. Accordingly, embodiments of the invention allow for three-dimensional integration of dies having differing packaging technologies. Furthermore, embodiments of the invention allow for the three-dimensional integration of dies that differ in form factor, in that dies of different geometries could be stacked to form the final three-dimensional microelectronic package.

An additional feature offered by embodiments of the invention, provided that ceramic (insulating) heat spreaders are used, is the use of the heat spreaders as additional routing planes and additional planes for the connection of the integrated circuit to the packaging substrate. This means that less routing need be done within the die or the package, thus saving valuable design real estate.

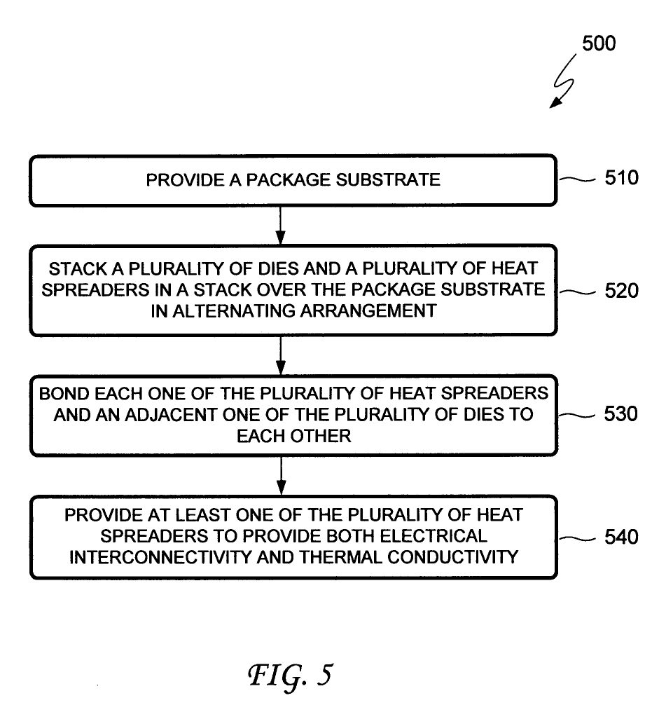

FIG. 5 is a flowchart illustrating a method 500 of manufacturing a microelectronic package according to an embodiment of the invention. A step 510 of method 500 is to provide a package substrate. As an example, the package substrate can be similar to package substrate 110, first shown in FIG. 1.

A step 520 of method 500 is to stack a plurality of dies and a plurality of heat spreaders in a stack over the package substrate in alternating arrangement. As an example, the plurality of dies and the plurality of heat spreaders can be similar to, respectively, plurality of dies 120 and plurality of heat spreader 130, both of which were first shown in FIG. 1. As another example, step 520 may result in a stack that is similar to stack 150 that was also first shown in FIG. 1.

In one embodiment, step 520 comprises positioning one of the plurality of heat spreaders between each pair of adjacent dies and positioning each one of the plurality of heat spreaders such that it has an extending portion that extends laterally beyond an edge of an adjacent die. As an example, the extending portion can be similar to extending portions 132 that are shown in FIG. 1. In the same or another embodiment, step 520 comprises interlocking the plurality of dies and the plurality of heat spreaders in order to hold the stack in place prior to bonding.

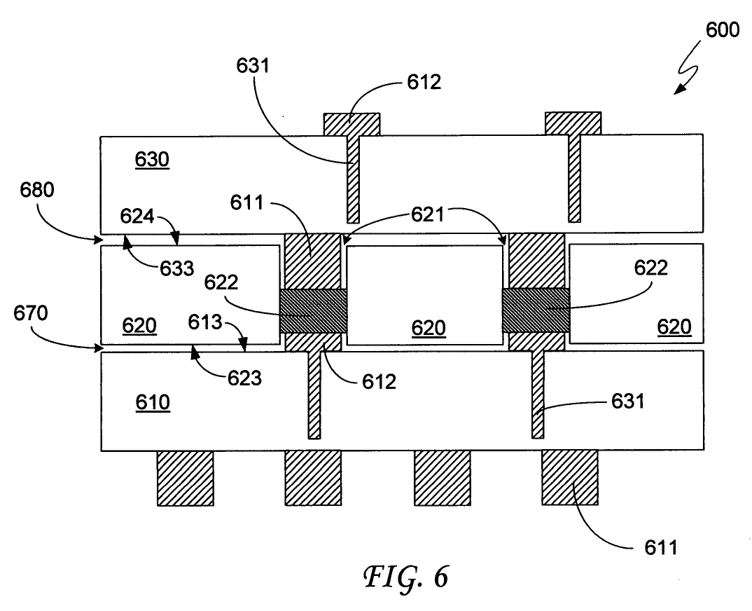

An example of how the referenced interlocking action may be accomplished is shown FIG. 6, which is a cross-sectional view of a portion of a microelectronic package 600 according to an embodiment of the invention. As illustrated in FIG. 6, microelectronic package 600 comprises dies 610 and 630 to which a plurality of flip chip interconnects 611 are attached. A heat spreader 620 is located between die 610 and die 630. Dies 610 and 630 contain TSVs 631. Heat spreader 620 contains THSVs 621 inside which is solder or another bonding material 622. Solder material 622 may be pre-loaded inside THSVs 621, or it may be loaded onto pads 612 at the backside of die 610. The presence inside THSVs 621 of flip chip interconnects 611 and pads 612 allow the interlocking action mentioned above and lock heat spreader 620 and dies 610 and 630 into a stack, maintaining the stack structure until a bonding step can be performed.

Prior to the bonding step, gaps 670 and 680 exist between heat spreader 620 and dies 610 and 630. The bonding step forms a tight bond between a lower surface 623 of heat spreader 620 and a backside surface 613 of die 610, removing gap 670 in the process. It is possible that the bonding step will also form a tight bond between an upper surface 624 of heat spreader 620 and a lower surface 633 of die 630, thus removing gap 680 as well. If that occurs, heat spreader 620 may be able to remove heat from die 630 as effectively as it is able to remove heat from die 610, thus increasing the efficiency of microelectronic package 600.

A step 530 of method 500 is to bond each one of the plurality of heat spreaders and an adjacent one of the plurality of dies to each other. In one embodiment, step 530 comprises bonding a particular heat spreader to a first adjacent die below the particular heat spreader prior to stacking a second adjacent die above the particular heat spreader. This embodiment entails a separate die attach and subsequent encapsulation of each die prior to the placement of the adjacent heat spreader above the die. Following such die attach and encapsulation actions, the adjacent heat spreader is attached to the die and subsequently the next die is attached to the aforementioned adjacent heat spreader and encapsulated. This process requires several reflows of the solder during die attach and a higher number of thermal cycles. It can also result in a higher warpage of the lowest dies, making the attachment of the lowest (first) heat spreader challenging. This embodiment allows for a sequential chip attach process and a standard capillary underfill procedure.

In a different embodiment, step 530 comprises performing a single bonding step after each one of the plurality of heat spreaders and each one of the plurality of dies have been stacked in the microelectronic package. In this embodiment, only one thermal step is necessary for the fabrication of the entire microelectronic package, thus minimizing possible warpage problems due to thermal cycling and allowing for optimal thermal management. If step 530 comprises only a single bonding step as just described, step 520 will likely require the interlocking action as described above so that the stack stays intact until its components are bonded together.

In one embodiment, step 530 comprises functionalizing a bonding surface with a chemical group that will crosslink and form a stable bond. As known in the art, one way to obtain a bonded interface with a low thermal resistance is to functionalize the surfaces to be bonded (e.g., the bottom of a heat spreader and the top of a die) with chemical groups that will crosslink at elevated temperatures (or with ultraviolet (UV) radiation in the case of diamond or AlN) and form a stable bond. This method has the advantage that the bonding interface is extremely thin and thus will result in a negligible thermal resistance across the interface for short molecules. As an example, the thickness of the thermal interface thus formed should be well below 100 nanometers (nm). The functionalizing molecules can be carbon-based or silicon-based short oligomeres or monomers. In embodiments where diamond is used as the material for the heat spreaders, or where the interface to a die is diamond, carbon-based monomers will form a stable and strong carbon-carbon bond to the diamond and a carbon-silicon-bond to the silicon die and will crosslink during the bonding step.

Another option is to use silicon-based molecules such as hexamethyldisiloxane (HMDS), hexamethyldisilazane, hexachlorodisiloxane, or the like so as to form a strong covalent bond between diamond nanoparticles. This approach results in a nearly ideal Si/Diamond interface but it necessitates very smooth (roughness RMS ˜1 nm) and coplanar surfaces. These roughness values are standard for Si and can be obtained easily for diamond at least on the nucleation side, rendering additional polishing obsolete and reducing the cost. In the case of AlN or SiC, the materials would have to be polished to the necessary specifications. Using longer molecules reduces the surface roughness criteria, but also leads to larger thermal resistances. The final choice will depend on bonding strength, overall thermal interface resistance and the targeted application.

In a different embodiment, step 530 comprises using a thermal interface material (TIM) to form a bond. As an example, a metal may be used as the TIM. This idea follows already well established heat spreader attachment schemes except that as in the previous bonding design the thickness of the overall thermal interface is anticipated to be far less than existing thermal interface thicknesses. The thickness of the TIM will depend on the roughness of the surfaces to be bonded. Both the heat spreader side that is to be bonded to the die and the die backside have to be first coated with a metal or metal layer stack that allows for good adhesion to the material and for wetting of a solder metal that serves as the bonding agent (usually a single metal with a lower melting point such as indium (In)). During the thermally activated bonding/adhesion step the solder liquefies and allows for a compliant interface between the two substances, thus alleviating surface roughness-related bounding problems. In order to minimize the thermal interface resistance it is clear that the two surfaces should be atomically smooth and coplanar to allow for a minimized overall metal thickness (to below 100 nm total). This technology, however, allows for less stringent requirements regarding surface roughness with respect to the previously-described bonding embodiment. One important restraint for this technology is that the interface metal must not cause a short between the vias, since that would render the whole microelectronic package useless. Therefore, a keep out zone (possibly defined by lithography) must be placed between the TIM and the via to ensure that no short is generated during the adhesion/bonding step.

A step 540 of method 500 is to provide at least one of the plurality of heat spreaders to provide both electrical interconnectivity and thermal conductivity. As an example, the electrical interconnectivity may be provided by through heat spreader vias that are similar to vias 137 that are shown in FIG. 1.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and related manufacturing methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

1. A microelectronic package comprising:
a package substrate;
a plurality of dies arranged in a stack above the package substrate, with a first die located above the package substrate at a bottom of the stack and an uppermost die located at a top of the stack; and
a plurality of heat spreaders stacked above the first die, with a first heat spreader of the plurality of heat spreaders located above the uppermost die, wherein:
at least one of the plurality of heat spreaders is no larger than an adjacent die such that no part of the at least one heat spreader extends beyond a perimeter of the adjacent die;
a surface of each one of the plurality of heat spreaders is in direct physical contact with a surface of any adjacent die;
one of the plurality of heat spreaders is located between each pair of adjacent dies; and
at least one of the plurality of heat spreaders provides both electrical interconnectivity and thermal conductivity.

2. (canceled)

3. The microelectronic package of claim 1 wherein:
the plurality of heat spreaders are made of diamond.

4. The microelectronic package of claim 1 wherein:
the plurality of heat spreaders are made of diamond-like carbon; and
the diamond-like carbon is electrically insulating.

5. The microelectronic package of claim 1 wherein:
the electrical interconnectivity of the at least one of the plurality of heat spreaders is provided by a through heat spreader via.

6. The microelectronic package of claim 5 wherein:
at least one of the plurality of dies contains a through via.

7. The microelectronic package of claim 1 wherein:
the first die is electrically and physically connected to the package substrate via a flip chip connection.

8. The microelectronic package of claim 7 wherein:
at least one of the plurality of dies is electrically and physically connected to the package substrate via a wire bond connection.

9. The microelectronic package of claim 1 further comprising:
a heat sink above the first heat spreader.

10. A method of manufacturing a microelectronic package, the method comprising:
providing a package substrate;
stacking a plurality of dies and a plurality of heat spreaders in a stack over the package substrate in alternating arrangement; and
bonding each one of the plurality of heat spreaders and an adjacent one of the plurality of dies to each other.

11. The method of claim 10 wherein:
stacking the plurality of dies and the plurality of heat spreaders comprises:
positioning one of the plurality of heat spreaders between each pair of adjacent dies; and
positioning each one of the plurality of heat spreaders such that it has an extending portion that extends laterally beyond an edge of an adjacent die; and
the method further comprises providing at least one of the plurality of heat spreaders to provide both electrical interconnectivity and thermal conductivity.

12. The method of claim 10 wherein:
bonding each one of the plurality of heat spreaders and an adjacent one of the plurality of dies to each other comprises bonding a particular heat spreader to a first adjacent die below the particular heat spreader prior to stacking a second adjacent die above the particular heat spreader.

13. The method of claim 10 wherein:
bonding each one of the plurality of heat spreaders and an adjacent one of the plurality of dies to each other comprises performing a single bonding step after each one of the plurality of heat spreaders and each one of the plurality of dies have been stacked in the microelectronic package.

14. The method of claim 13 wherein:
stacking the plurality of dies and the plurality of heat spreaders comprises interlocking the plurality of dies and the plurality of heat spreaders in order to hold the stack in place prior to bonding.

15. The method of claim 10 wherein:
bonding each one of the plurality of heat spreaders and an adjacent one of the plurality of dies to each other comprises functionalizing a bonding surface with a chemical group that will crosslink and form a stable bond.

16. The method of claim 10 wherein:
bonding each one of the plurality of heat spreaders and an adjacent one of the plurality of dies to each other comprises using a thermal interface material to form a bond.
